(19) United States
(12) Patent Application Publication
(10) Pub. No.: US 2025/0210366 A1
(43) Pub. Date: Jun. 26, 2025

(54) MANUFACTURING METHOD OF SEMICONDUCTOR DEVICE

(71) Applicant: Kioxia Corporation, Tokyo (JP)

(72) Inventor: Hakuba KITAGAWA, Yokkaichi Mie (JP)

(73) Assignee: Kioxia Corporation, Tokyo (JP)

(21) Appl. No.: 18/816,817

(22) Filed: Aug. 27, 2024

(30) Foreign Application Priority Data
Dec. 21, 2023 (JP) 2023-215975

(51) Int. Cl. H01L 21/311; C09K 13/08; H01L 21/768

(52) U.S. Cl. CPC H01L 21/31111; C09K 13/08; H01L 21/768

(57) ABSTRACT

An etching method according to the present embodiment includes etching a structure from inside of a hole or a slit provided in the structure, using a chemical etching solution containing an acid and a polymer.

### CROSS REFERENCE TO RELATED APPLICATIONS

This application is based upon and claims the benefit of priority from the prior Japanese Patent Application No. 2023-215975, filed on Dec. 21, 2023, the entire contents of which are incorporated herein by reference.

### FIELD

The embodiments of the present invention relate to a manufacturing method of a semiconductor device.

### BACKGROUND

A semiconductor storage device such as a NAND flash memory may have a three-dimensional memory cell array in which a plurality of memory cells are arranged in three dimensions. With further downscaling and multi-layering of the memory cell array, an aspect ratio of memory holes, contact holes, and the like increases. In a step of forming the holes such as the memory holes and contact holes with a high aspect ratio, a phenomenon occurs in which the hole has a smaller diameter at its bottom than the diameter at its top (so-called loading).

### BRIEF DESCRIPTION OF THE DRAWINGS

FIG. 1 is a block diagram illustrating a configuration example of a semiconductor device according to a first embodiment;

FIG. 2 is a circuit diagram illustrating an example of a circuit configuration of a memory cell array according to the first embodiment;

FIG. 3 is a plan view illustrating an example of a planar layout of the memory cell array according to the first embodiment;

FIG. 4 is a plan view illustrating an example of the planar layout of a memory area of the memory cell array according to the first embodiment;

FIG. 5 is a diagram illustrating an example of a cross-sectional structure of the memory area of the memory cell array according to the first embodiment;

FIG. 6 is a diagram illustrating an example of a cross-sectional structure of the memory area of the memory cell array according to the first embodiment;

FIG. 7 is a diagram illustrating an example of a cross-sectional structure of a memory pillar according to the first embodiment;

FIG. 8 is a cross-sectional view illustrating an example of a manufacturing method of the semiconductor device according to the first embodiment;

FIG. 9 is a cross-sectional view illustrating an example of a manufacturing method of the semiconductor device subsequent to FIG. 8;

FIG. 10 is a cross-sectional view illustrating an example of a manufacturing method of the semiconductor device subsequent to FIG. 9;

FIG. 11 is a cross-sectional view illustrating an example of a manufacturing method of the semiconductor device subsequent to FIG. 10;

FIG. 12 is a cross-sectional view illustrating an example of a manufacturing method of the semiconductor device subsequent to FIG. 11;

FIG. 13 is a cross-sectional view illustrating an example of a manufacturing method of the semiconductor device subsequent to FIG. 12;

FIG. 14 is a cross-sectional view illustrating an example of a manufacturing method of the semiconductor device subsequent to FIG. 13;

FIG. 15 is a cross-sectional view illustrating an example of a manufacturing method of the semiconductor device subsequent to FIG. 14;

FIG. 16 is a cross-sectional view illustrating an example of a formation step of memory holes according to the first embodiment;

FIG. 17 is a cross-sectional view illustrating an example of a formation step of the memory holes subsequent to FIG. 16;

FIG. 18 is a cross-sectional view illustrating an example of a formation step of the memory holes subsequent to FIG. 17;

FIG. 19 is a cross-sectional view illustrating an example of a formation step of the memory holes subsequent to FIG. 18;

FIG. 20 is a graph illustrating a relationship between a molecular weight of a polymer and an inverse loading effect;

FIG. 21 is a perspective view illustrating an example of a configuration of lead-out areas according to a second modification of the first embodiment; and

FIG. 22 is a perspective view illustrating an example of a configuration of the lead-out areas according to the second modification of the first embodiment.

### DETAILED DESCRIPTION

In general, according to the embodiment, an etching method comprises etching a structure from inside of a hole or a slit provided in the structure, using a chemical etching solution containing an acid and a polymer. Hereinafter, the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First Embodiment

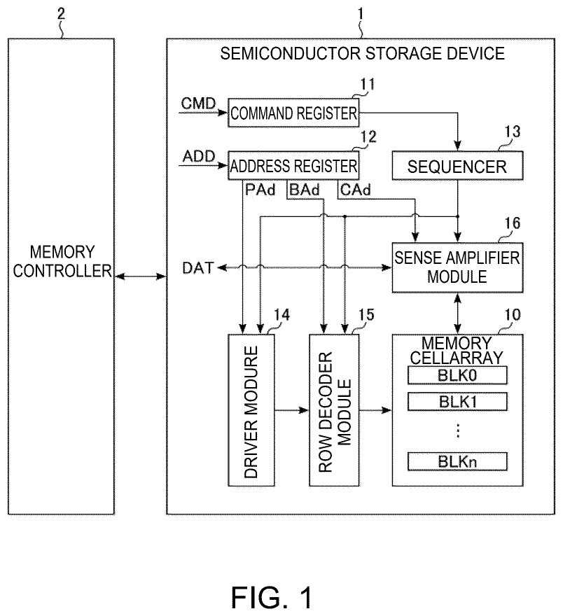

FIG. 1 is a block diagram illustrating a configuration example of a semiconductor device according to a first embodiment. A semiconductor device 1 is a NAND flash memory capable of storing therein data in a nonvolatile manner. The semiconductor device 1 is controlled by an external memory controller 2.

The semiconductor device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (n is an integer equal to or larger than 1). The block BLK is a set of memory cells capable of storing data in a nonvolatile manner. For example, the block BLK is used as a unit of data erasure. The memory cell array 10 is provided with a plurality of bit lines and a plurality of word lines. For example, each memory cell is associated with a single bit line and a single word line. The configuration of the memory cell array 10 is described later in detail.

The command register 11 holds a command CMD received by the semiconductor device 1 from the memory controller 2. For example, the command CMD includes instructions to cause the sequencer 13 to perform a read operation, a write operation, an erase operation, or other operations.

The address register 12 holds address information ADD received by the semiconductor device 1 from the memory controller 2. Examples of the address information ADD include a block address BAd, a page address PAd, and a column address CAd. For example, the block address BAd, the page address PAd, and the column address CAd are used respectively to select the block BLK, the word line, and the bit line.

The sequencer 13 controls the entire operation of the semiconductor device 1. For example, the sequencer 13 controls the driver module 14, the row decoder module 15, the sense amplifier module 16, and other modules based on the command CMD held in the command register 11 to perform a read operation, a write operation, an erase operation, or other operations.

The driver module 14 generates a voltage to be used in the read operation, the write operation, the erase operation, or other operations. The driver module 14 then applies the generated voltage to a signal line corresponding to the selected word line based on, for example, a page address PAd held in the address register 12.

Based on the block address BAd held in the address register 12, the row decoder module 15 selects one corresponding block BLK in the memory cell array 10. For example, the row decoder module 15 then transfers the voltage, applied to the signal line corresponding to the selected word line, to this selected word line in the selected block BLK.

In the write operation, the sense amplifier module 16 applies a desired voltage to each bit line in response to write data DAT received from the memory controller 2. In the read operation, the sense amplifier module 16 determines the data stored in the memory cell based on the voltage of the bit line, and transfers the determination result to the memory controller 2 as read data DAT.

The semiconductor device 1 and the memory controller 2 may be combined into a single unit of semiconductor device. Examples of this semiconductor device include a memory card such as an SD™ card and an SSD (Solid State Drive).

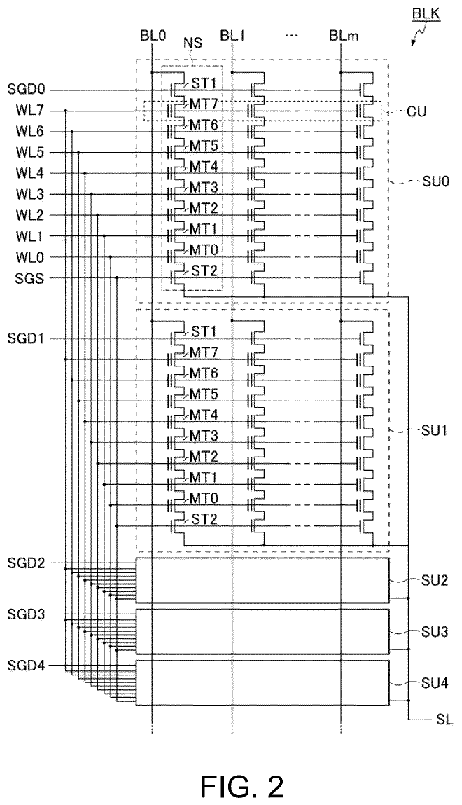

FIG. 2 is a circuit diagram illustrating an example of a circuit configuration of the memory cell array according to the first embodiment. FIG. 2 illustrates the block BLK which is one of the blocks BLK included in the memory cell array 10. The block BLK includes, for example, five string units SU0 to SU4.

Each string unit SU includes a plurality of NAND strings NS that are respectively associated with bit lines BL0 to BLm (m is an integer equal to or larger than 1). Each of the NAND strings NS includes, for example, memory cell transistors MT0 to MT7 and selection transistors ST1 and ST2. Each memory cell transistor MT includes a control gate and a charge storage layer, and holds data in a nonvolatile manner. Each of the selection transistors ST1 and ST2 is used to select the string unit SU for each of the 25 various operations.

In each of the NAND strings NS, the memory cell transistors MT0 to MT7 are connected in series. A drain of the selection transistor ST1 is connected to an associated bit line BL. A source of the selection transistor ST1 is connected to one end of the memory cell transistors MT0 to MT7 connected in series. A drain of the selection transistor ST2 is connected to the other end of the memory cell transistors MT0 to MT7 connected in series. A source of the selection transistor ST2 is connected to a source line SL.

Control gates of the memory cell transistors MT0 to MT7 in the same block BLK are connected respectively to the word lines WL0 to WL7. Gates of a plurality of selection transistors ST1 in the string unit SU0 are connected to a selection gate line SGD0. Gates of a plurality of selection transistors ST1 in the string unit SU1 are connected to a selection gate line SGD1. Gates of a plurality of selection transistors ST1 in the string unit SU2 are connected to a selection gate line SGD2. Gates of a plurality of selection transistors ST1 in the string unit SU3 are connected to a selection gate line SGD3. Gates of a plurality of selection transistors ST1 in the string unit SU4 are connected to a selection gate line SGD4. Gates of a plurality of selection transistors ST2 are connected to a selection gate line SGS.

Different column addresses are assigned to the bit lines BL0 to BLm. Each bit line BL is shared by NAND strings NS assigned with the same column address between the blocks BLK. The word lines WL0 to WL7 are provided for each block BLK. For example, the source line SL is shared between the blocks BLK.

A set of memory cell transistors MT connected to the common word line WL in a single string unit SU is referred to as, for example, “cell unit CU”. For example, the storage capacity of the cell unit CU including the memory cell transistors MT, each of which stores 1-bit data, is defined as “one page of data”. The cell unit CU may have a storage capacity of two or more pages of data according to the number of data bits to be stored by the memory cell transistors MT.

The memory cell array 10 included in the semiconductor device 1 according to the embodiment may have a circuit configuration other than the circuit configuration described above. For example, it is allowable to set the number of string units SU to be included in each block BLK to any number, and set the number of memory cell transistors MT and the number of selection transistors ST1 and ST2 to be included in each NAND string NS to any number.

An example of the structure of the memory cell array 10 included in the semiconductor device 1 according to the embodiment is described below. In the drawings to be referenced below, the X direction corresponds to the extending direction of the word line WL, the Y direction corresponds to the extending direction of the bit line BL, and the Z direction corresponds to the direction vertical to the surface of a semiconductor substrate 20 used to form the semiconductor device 1. Hatching is added to the plan views to make them easier to see, and is not necessarily related to the material or characteristics of the constituent element added with the hatching. In the cross-sectional views, illustrations of the configuration are appropriately omitted to make these cross-sectional views easier to see. Further, the configuration illustrated in each drawing is appropriately simplified.

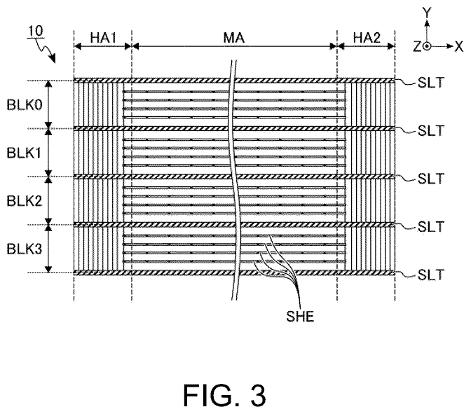

FIG. 3 is a plan view illustrating an example of the planar layout of the memory cell array according to the first embodiment. FIG. 3 illustrates areas corresponding to four blocks BLK0 to BLK3 included in the memory cell array 10. The planar layout of the memory cell array 10 is divided into, for example, a memory area MA and lead-out areas HA1 and HA2 in the X direction. For example, the memory cell array 10 includes a plurality of slits SLT and a plurality of slits SHE. The semiconductor device 1 according to the present embodiment is a non-volatile memory including a three-dimensional structure of memory cell array.

The memory area MA includes a plurality of NAND strings NS. The memory area MA is sandwiched between the lead-out areas HA1 and HA2 in the X direction. The lead-out areas HA1 and HA2 are used to connect laminated wirings (the word lines WL and the selection gate lines SGD and SGS) and the row decoder module 15. For example, each of the lead-out areas HA1 and HA2 includes portions (terrace portions) where the selection gate line SGS, the word lines WL0 to WL7, and the selection gate line SGD do not overlap their respective upper wiring layers (conductor layers). In each block BLK, a plurality of contacts are provided on the respective terrace portions of the selection gate line SGS, the word lines WL0 to WL7, and the selection gate lines SGD0 to SGD4. For example, the contacts for the laminated wirings are provided in the lead-out area HA1 in an even-numbered block BLK, and in the lead-out area HA2 in an odd-numbered block BLK.

The plurality of slits SLT, each of which has a portion provided to extend along the X direction, are arranged parallel to each other in the Y direction. Each of the slits SLT extends across the memory area MA and the lead-out areas HA1 and HA2 in the X direction. Each of the slits SLT has a structure in which, for example, an insulator and a plate-like contact are filled. Each of the slits SLT divides the wirings adjacent to each other through the slit SLT (for example, the word lines WL0 to WL7, and the selection gate lines SGD and SGS). The slit SLT has an aspect ratio of, for example, 100 or higher.

The plurality of slits SHE, each of which has a portion provided to extend along the X direction, are arranged parallel to each other in the Y direction. In this example, four slits SHE are arranged between the adjacent slits SLT. Each of the slits SHE extends across the memory area MA in the X direction, and one end of the slit SHE is included in the lead-out area HA1, while the other end is included in the lead-out area HA2. Each of the slits SHE has a structure in which, for example, an insulator is filled. Each of the slits SHE divides the wirings adjacent to each other through the slit SHE (at least the selection gate line SGD).

On the planar layout of the memory cell array 10 described above, each of the areas divided from each other by the slits SLT corresponds to a single block BLK. Each of the areas divided from each other by the slits SLT and SHE corresponds to a single string unit SU. In the memory cell array 10, for example, the layout illustrated in FIG. 3 is repeated in the Y direction.

The planar layout of the memory cell array 10 may be any planar layout other than that illustrated in FIG. 3. For example, it is allowable to set the number of slits SHE to be arranged between the adjacent slits SLT to any number. It is allowable to change the number of string unit SU to be formed between the adjacent slits SLT, based on the number of slits SHE arranged between the adjacent slits SLT.

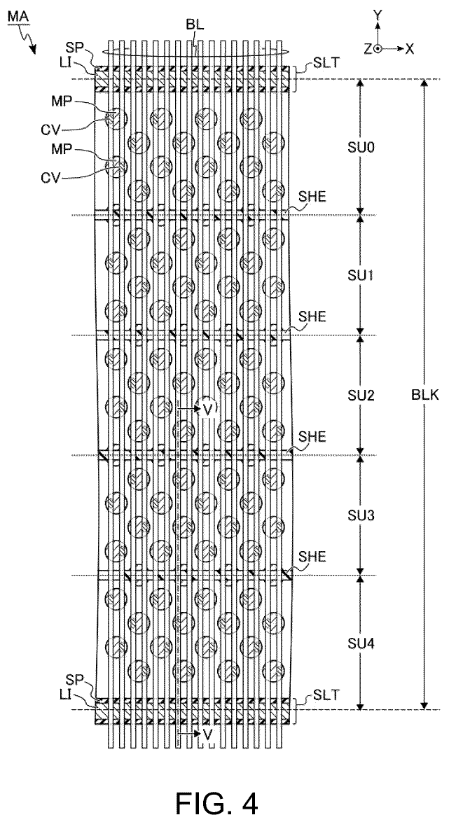

FIG. 4 is a plan view illustrating an example of the planar layout of the memory area of the memory cell array according to the first embodiment. FIG. 4 illustrates an area including a single block BLK (that is, string units SU0 to SU4). The memory cell array 10 includes a plurality of memory pillars MP, a plurality of contacts CV, and a plurality of bit lines BL in the memory area MA. Each of the slits SLT includes a contact LI and a spacer SP.

Each of the memory pillars MP serves as, for example, a single NAND string NS. The plurality of memory pillars MP are arranged, for example, in a staggered manner in 24 rows in the area between two adjacent slits SLT. For example, one slit SHE overlaps the memory pillars MP in the fifth row, one slit SHE overlaps the memory pillars MP in the 10th row, one slit SHE overlaps the memory pillars MP in the 15th row, and one slit SHE overlaps the memory pillars MP in the 20th row from the top side of the drawing of FIG. 4.

The plurality of bit lines BL, each of which has a portion provided to extend along the Y direction, are arranged parallel to each other in the X direction. Each of the bit lines BL is arranged in such a manner as to overlap at least one memory pillar MP in each string unit SU. In this example, two bit lines BL are arranged in such a manner so as to overlap one memory pillar MP. The bit line BL which is one of the plurality of bit lines BL overlapping the memory pillar MP, and this memory pillar MP are electrically connected through the contact CV.

For example, the contact CV is omitted between the bit line BL and the memory pillar MP that is in contact with the slit SHE. In other words, the contact CV is omitted between the bit line BL and the memory pillar MP that is in contact with two separate selection gate lines SGD. It is allowable to change the number and arrangement of the memory pillars MP and the number and arrangement of the slits SHE between the adjacent slits SLT as appropriate. Other configurations may also be employed. For example, it is allowable to set the number of bit lines BL overlapping each memory pillar MP to any number.

The contact LI is a conductor having a portion provided to extend in the X direction. The spacer SP is an insulator provided on the sides of the contact LI. The contact LI is sandwiched by the spacer SP. The contact LI is separated and insulated from conductors adjacent to this contact LI in the Y direction (for example, the word lines WL0 to WL7, and the selection gate lines SGD and SGS) by the spacer SP.

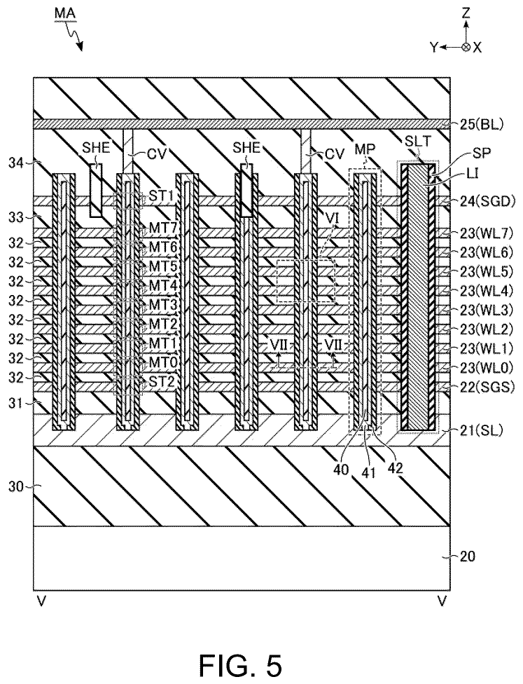

FIG. 5 is a diagram illustrating an example of the cross-sectional structure of the memory area of the memory cell array according to the first embodiment. FIG. 5 is a cross-sectional view taken along a line V-V in FIG. 4. The memory cell array 10 further includes, for example, a semiconductor substrate 20, conductor layers 21 to 25, and insulator layers 30 to 34.

Specifically, the insulator layer 30 is provided on the semiconductor substrate 20. Although not illustrated, the insulator layer 30 includes a circuit equivalent to, for example, the row decoder module 15 and the sense amplifier module 16.

The conductor layer 21 is provided on the insulator layer 30. The conductor layer 21 is formed in, for example, a plate-like shape extending over the XY-plane, and is used as the source line SL. The conductor layer 21 contains, for example, phosphorus-doped silicon.

The insulator layer 31 is provided on the conductor layer 21. The conductor layer 22 is provided on the insulator layer 31. The conductor layer 22 is formed in, for example, a plate-like shape extending over the XY-plane, and is used as the selection gate line SGS.

On the conductor layer 22, the insulator layers 32 and the conductor layers 23 are alternately laminated. The conductor layers 23 are formed in, for example, a plate-like shape extending over the XY-plane. A plurality of conductor layers 23 laminated one after another are used as the word lines WL0 to WL7 respectively in order from the lower side near the semiconductor substrate 20.

The insulator layer 33 is provided on the uppermost conductor layer 23. The conductor layer 24 is provided on the insulator layer 33. The conductor layer 24 is formed in, for example, a plate-like shape extending over the XY-plane, and is used as the selection gate line SGD.

The insulator layer 34 is provided on the conductor layer 24. The conductor layer 25 is provided on the insulator layer 34. The conductor layer 25 is formed linearly, for example, extending in the Y direction, and is used as the bit line BL. That is, in an area not illustrated in FIG. 5, a plurality of conductor layers 25 are arrayed in the X direction. The conductor layers 25 contain, for example, copper.

Each of the memory pillars MP is provided extending along the Z direction and penetrates the insulator layers 31 to 33 and the conductor layers 22 to 24. The bottom portion of each of the memory pillars MP is in contact with the conductor layer 21. An intersecting portion of the memory pillar MP and the conductor layer 22 serves as a selection transistor ST2. An intersecting portion of the memory pillar MP and one of the conductor layers 23 serves as one of the memory cell transistors MT. An intersecting portion of the memory pillar MP and the conductor layer 24 serves as a selection transistor ST1.

Each of the memory pillars MP includes, for example, a core member 40, a semiconductor layer 41, and a laminated film 42. The core member 40 is provided extending along the Z direction. For example, an upper end of the core member 40 is included in an upper layer relative to the conductor layer 24, while a lower end of the core member 40 reaches the conductor layer 21. The semiconductor layer 41 covers the circumference of the core member 40. In the lower portion of the memory pillar MP, the semiconductor layer 41 is partially in contact with the conductor layer 21. The laminated film 42 covers the lateral side and the bottom side of the semiconductor layer 41, except for a portion of the semiconductor layer 41 that is in contact with the conductor layer 21. The core member 40 is made of an insulating material such as silicon oxide. The semiconductor layer 41 contains, for example, silicon.

The contact CV in the form of a column is provided on the semiconductor layer 41 in the memory pillar MP. In the area illustrated in FIG. 5, two contacts CV respectively corresponding to two of the six memory pillars MP are shown. The memory pillar MP, which does not overlap the slit SHE or connect to the contact CV in the illustrated area of the memory area MA, is connected to the contact CV in an area of the memory area MA not illustrated in FIG. 5.

One conductor layer 25, that is one bit line BL, is in contact with the top of the contacts CV. One contact CV is connected to one conductor layer 25 in each of the spaces partitioned by the slits SLT and SHE. That is, the memory pillars MP provided between the slits SLT and SHE adjacent to each other, and the memory pillars MP provided between two adjacent slits SHE are electrically connected to each of the conductor layers 25.

The slit SLT has, for example, a portion provided to extend over the XZ-plane, and divides the conductor layers 22 to 24. The contact LI in the slit SLT is provided along the slit SLT. The upper end of the contact LI is partially in contact with the insulator layer 34. The lower end of the contact LI is in contact with the conductor layer 21. The contact LI is used as, for example, a portion of the source line SL. The spacer SP is provided at least between the contact LI and the conductor layers 22 to 24. The contact LI is separated and insulated from the conductor layers 22 to 24 by the spacer SP.

The slit SHE has, for example, a portion provided to extend over the XZ-plane, and at least divides the conductor layer 24. The upper end of the slit SHE is in contact with the insulator layer 34. The lower end of the slit SHE is in contact with the insulator layer 33. The slit SHE includes an insulator made of, for example, silicon oxide. The upper end of the slit SHE and the upper end of the slit SLT may or may not be aligned with each other. The upper end of the slit SHE and the upper end of the memory pillar MP may or may not be aligned with each other.

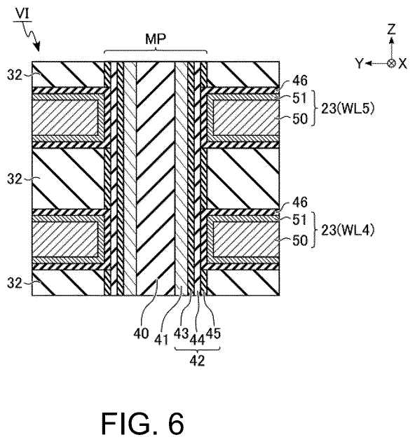

FIG. 6 is a diagram illustrating an example of the cross-sectional structure of the memory area MA of the memory cell array 10 according to the first embodiment. FIG. 6 is an enlarged view of an area VI in FIG. 5. Specifically, FIG. 6 illustrates the structure of the memory pillar MP and the conductor layers 23 at the intersecting portions of the memory pillar MP and the conductor layers 23. The laminated film 42 includes, for example, a tunnel dielectric film 43, an insulating film 44, and a cover dielectric film 45. Each of the conductor layers 23 includes, for example, a conductor 50 and a barrier metal 51. The memory cell array 10 further includes block dielectric films 46.

The tunnel dielectric film 43 is provided on the lateral side of the semiconductor layer 41. The insulating film 44 is provided on the lateral side of the tunnel dielectric film 43. The cover dielectric film 45 is provided on the lateral side of the insulating film 44. The cover dielectric film 45 is separated from the conductor layers 23 by the block dielectric films 46 at the intersecting portions of the memory pillar MP and the conductor layers 23. Each of the block dielectric films 46 is provided between the conductor layer 23 and the insulator layer 32 and between the conductor layer 23 and the insulating film 44. The conductor 50 is filled in a space defined by three sides of the block dielectric film 46. The conductor 50 and the block dielectric film 46 are separated from each other by the barrier metal 51.

An insulating material such as silicon oxide, silicon nitride, or a silicon oxynitride film is used for the tunnel dielectric film 43. The cover dielectric film 45 contains, for example, silicon oxide.

The insulating film 44 contains, for example, silicon nitride. The block dielectric film 46 contains, for example, aluminum oxide (Al₂O₃). The block dielectric film 46 is also used as a seed layer to form a film on the conductor 50. The conductor 50 contains molybdenum (Mo). The conductor 50 may contain impurities. Examples of the impurities that can be contained in the conductor 50 include oxygen (O) and hydrogen (H). The barrier metal 51 contains, for example, titanium nitride (TiN).

It is allowable that the barrier metal 51 is omitted. Instead of the cover dielectric film 45, the block dielectric film 46 may be provided on the lateral side portion of the memory pillar MP. The structure of the conductor layer 22 and the memory pillar MP at their intersecting portion, and the structure of the conductor layer 24 and the memory pillar MP at their intersecting portion are both identical to the structure of the conductor layer 23 and the memory pillar MP at their intersecting portion.

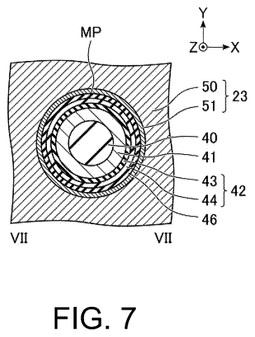

FIG. 7 is a diagram illustrating an example of a cross-sectional structure of the memory pillar according to the first embodiment. FIG. 7 is a cross-sectional view taken along a line VII-VII in FIG. 5. Specifically, FIG. 7 illustrates the cross-sectional structure of the memory pillar MP in cross-section parallel to the surface of the semiconductor substrate 20 and including the conductor layer 23. In the cross-section including the conductor layer 23, the core member 40 is provided in the central portion of the memory pillar MP. The semiconductor layer 41 surrounds the lateral side of the core member 40. The tunnel dielectric film 43 surrounds the lateral side of the semiconductor layer 41. The insulating film 44 surrounds the lateral side of the tunnel dielectric film 43. The block dielectric film 46 surrounds the lateral side of the insulating film 44. The barrier metal 51 surrounds the lateral side of the block dielectric film 46. The conductor layer 23 surrounds the lateral side of the barrier metal 51.

The structure of the conductor layer 22 and the memory pillar MP in cross-section parallel to the surface of the semiconductor substrate 20 and including the conductor layer 22, and the structure of the conductor layer 24 and the memory pillar MP in cross-section parallel to the surface of the semiconductor substrate 20 and including the conductor layer 24 are both identical to the structure of the conductor layer 23 and the memory pillar MP in cross-section parallel to the surface of the semiconductor substrate 20 and including the conductor layer 23. In each of the memory pillars MP described above, the semiconductor layer 41 is used as a channel (current path) of the memory cell transistors MT0 to MT7 and the selection transistors ST1 and ST2. The insulating film 44 is used as a charge storage layer of the memory cell transistors MT. The semiconductor device 1 can pass an electric current through the memory pillars MP between the bit line BL and the contact LI by switching on the memory cell transistors MT0 to MT7 and the selection transistors ST1 and ST2.

Next, a manufacturing method of the semiconductor device 1 according to the present embodiment is described.

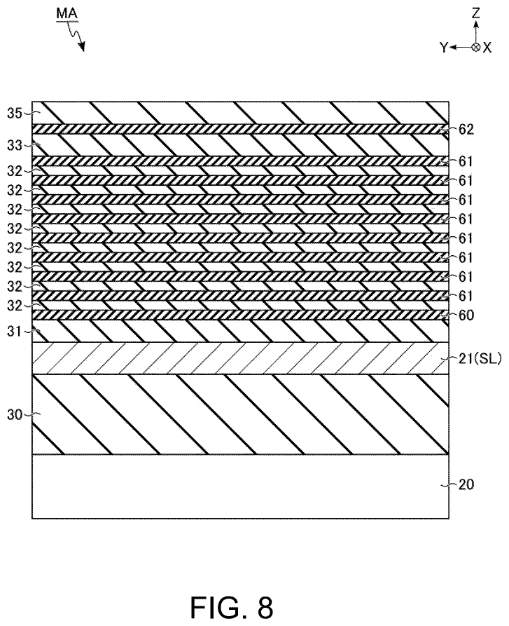

FIGS. 8 to 15 are cross-sectional views illustrating an example of the manufacturing method of the semiconductor device according to the first embodiment.

As illustrated in FIG. 8, a CMOS (Complementary Metal Oxide Semiconductor) circuit (not illustrated) equivalent to the row decoder module 15 and other modules is formed on the semiconductor substrate 20, and the insulator layer 30 covering the CMOS circuit is further formed thereon. It is allowable that the CMOS circuit is formed on another semiconductor substrate (not illustrated). In this case, after the memory area MA is formed on the semiconductor substrate 20, another semiconductor substrate having the CMOS circuit formed thereon may be bonded onto the semiconductor substrate having the memory area MA formed thereon.

Next, the conductor layer 21 is formed on the insulator layer 30. On the conductor layer 21, the insulator layer 31 and a sacrificial member 60 are formed in the order described. On the sacrificial member 60, the insulator layers 32 and sacrificial members 61 are alternately laminated. On the uppermost layer of the sacrificial member 61, the insulator layer 33 and a sacrificial member 62 are formed in the order described. On the sacrificial member 62, an insulator layer 35 is formed. The sacrificial member 60 is associated with the selection gate line SGS. The sacrificial members 61 are associated with the word lines WL. The sacrificial member 62 is associated with the selection gate line SGD. Each of the sacrificial members 60, 61, and 62 is, for example, a material containing nitrogen and silicon (for example, silicon nitride). Each of the insulator layers 30 to 33 and 35 is, for example, a material containing oxygen and silicon (for example, silicon oxide film).

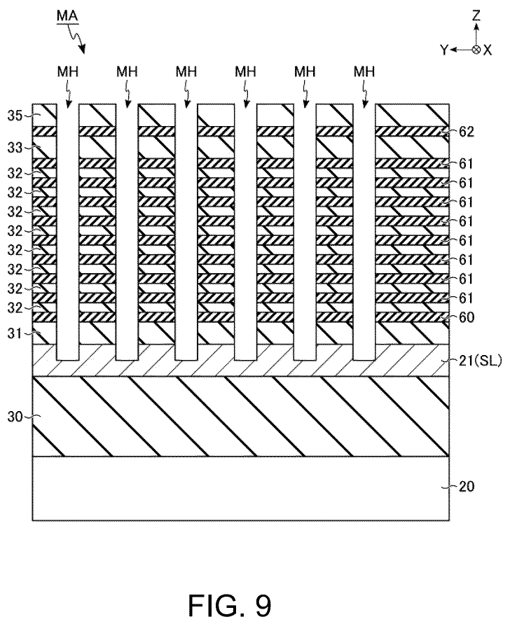

Subsequently, as illustrated in FIG. 9, memory holes MH are formed. Specifically, a mask (not illustrated) is formed in which areas corresponding to the plurality of memory pillars MP are opened. A plurality of memory hole MH are formed by an anisotropic etching process using the mask. The memory holes MH penetrate the insulator layers 31, 32, 33, and 35 and the sacrificial members 60, 61, and 62. The bottom portion of the memory holes MH reaches the conductor layer 21.

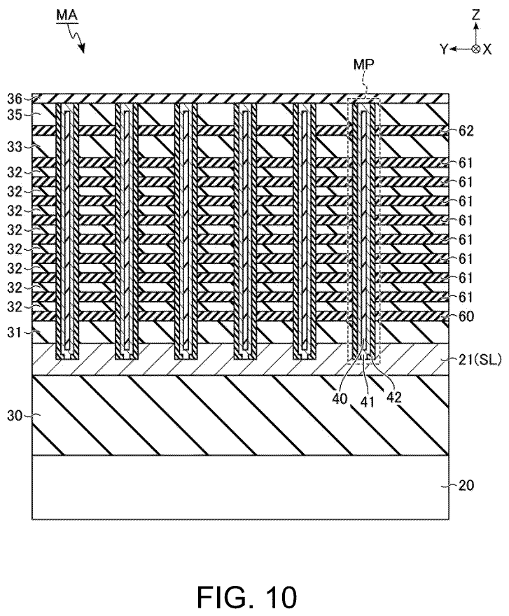

Next, as illustrated in FIG. 10, the memory pillars MP are formed. Specifically, the cover dielectric film 45, the insulating film 44, and the tunnel dielectric film 43 are formed in the order described on the lateral side and the bottom side of the plurality of memory holes MH. Consequently, a laminated film of the cover dielectric film 45, the insulating film 44, and the tunnel dielectric film 43 is formed. The cover dielectric film 45, the insulating film 44, and the tunnel dielectric film 43 provided at the bottom portion of the memory holes MH are partially removed. The semiconductor layer 41 and the core member 40 are formed in the memory holes MH. The core member 40 provided in the top portion of the memory holes is then partially removed, and the semiconductor layer 41 is formed in this removed part of the core member 40. Consequently, a structure of the plurality of memory pillars MP is formed. Thereafter, an insulator layer 36 is formed on the insulator layer 35 and the plurality of memory pillars MP. The insulator layer 36 protects the top portion of the memory pillars MP. The insulator layers 35 and 36 are included in the insulator layer 34 illustrated in FIG. 5.

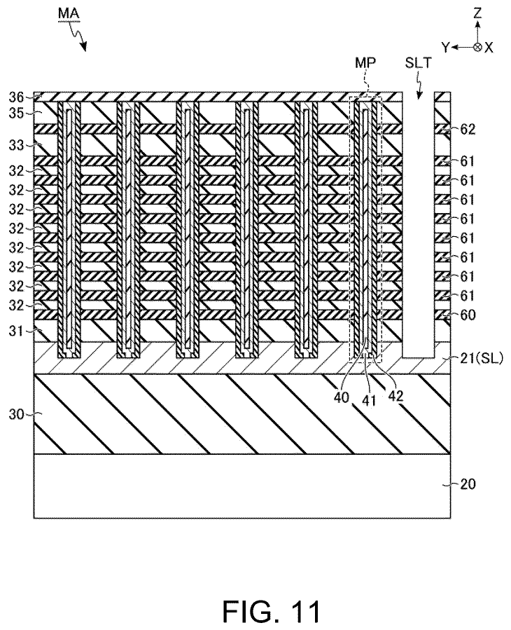

Subsequently, as illustrated in FIG. 11, the slit SLT is formed. Specifically, a mask is formed in which an area corresponding to the slit SLT is opened by photolithography or other processes. The slit SLT is then formed by anisotropic etching using the mask in such a manner that the slit SLT divides each of the insulator layers 31, 32, 33, 35, and 36 and the sacrificial members 60, 61, and 62. The bottom portion of the slit SLT reaches, for example, the conductor layer 21. It is allowable to, after the formation of the slit SLT, perform a process of forming a protective film for the conductor layer 21 exposed at the bottom portion of the slit SLT.

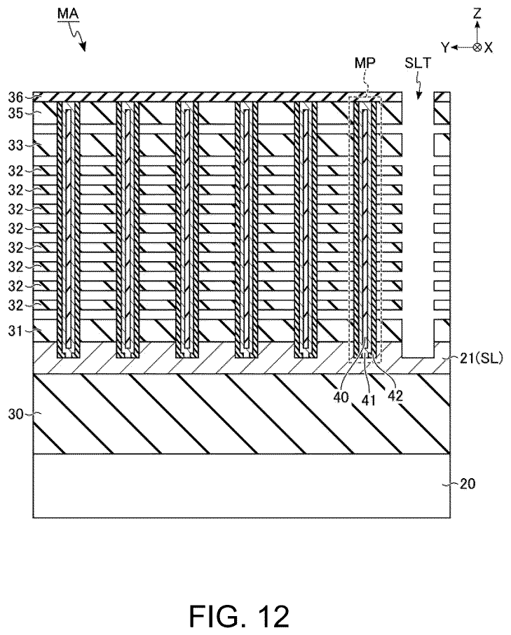

Next, as illustrated in FIG. 12, the sacrificial members 60, 61, and 62 are removed. Specifically, a wet etching process using a thermal phosphoric acid or the like is performed. More specifically, the sacrificial members 60, 61, and 62 are selectively removed by being supplied with the thermal phosphoric acid or the like through the slit SLT. Although not illustrated, the cover dielectric film 45 provided in a portion of each memory pillar MP that is in contact with any of the sacrificial member 60, 61, or 62 is removed. The structure from which the sacrificial members 60, 61, and 62 have been removed is supported by a plurality of memory pillars MP and other elements.

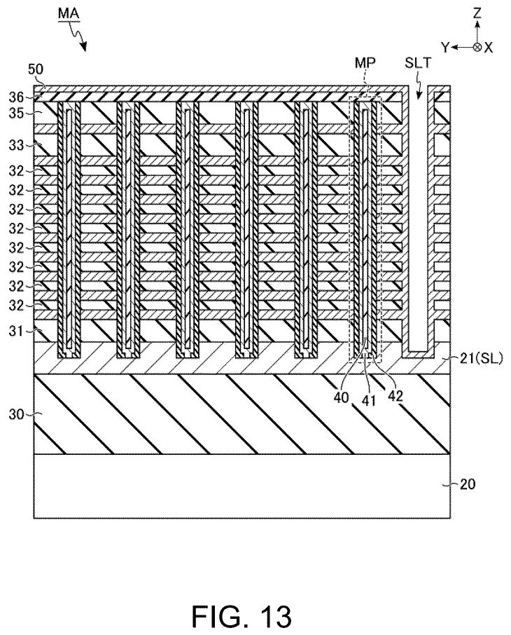

Subsequently, as illustrated in FIG. 13, the conductors 50 are formed. Specifically, the block dielectric film 46 and the barrier metal 51 in FIG. 6 are formed in the order described. The block dielectric film 46 is formed by using, for example, the thermal CVD (Chemical Vapor Deposition) method or the ALD (Atomic Layer Deposition) method. The conductors 50 are filled in spaces from which the sacrificial members 60 to 62 have been removed. The conductors 50 are formed by using, for example, the thermal CVD method or the ALD method. The block dielectric film 46, the barrier metal 51, and the conductor 50 are also formed on the lateral side portion of the slit SLT and the top side portion of the insulator layer 36. At this point, the conductors 50 formed in the spaces from which the sacrificial members 60 to 62 have been removed are continuously provided and electrically connected to each other.

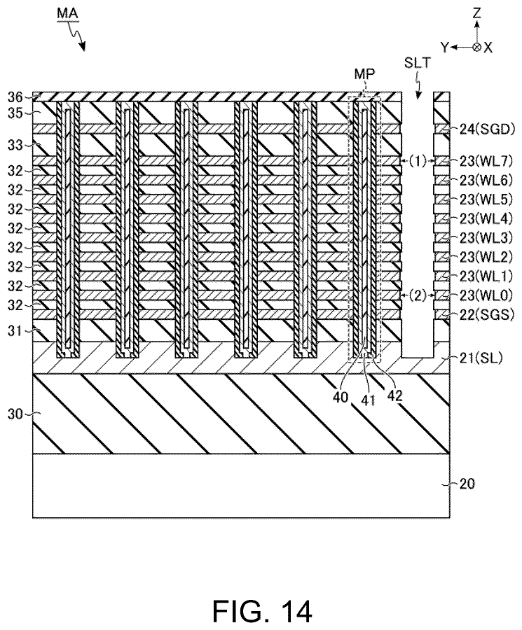

Next, as illustrated in FIG. 14, an etching process is performed on the conductors 50. Specifically, the conductor 50 formed on the lateral side of the slit SLT, and the conductor 50 formed on the top side of the insulator layer 36 are removed by using the wet etching method. It suffices that at least the conductors 50 formed on the wiring layers adjacent to each other in the Z direction are separated from each other. Consequently, the conductor layer 22 that serves as the selection gate line SGS, the plurality of conductor layers 23 that serve as the word lines WL0 to WL7 respectively, and the conductor layer 24 that serves as the selection gate line SGD are formed.

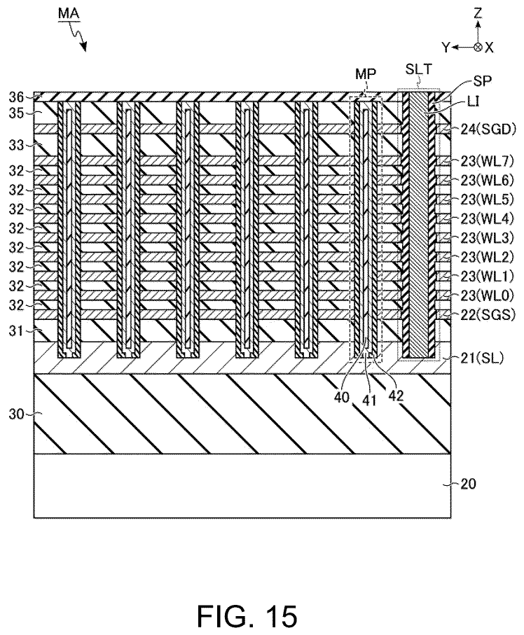

Subsequently, as illustrated in FIG. 15, a process of filling the slit SLT is performed. Specifically, an insulating film (spacer SP) is formed in such a manner as to cover the sides and the bottom of the slit SLT. A portion of the spacer SP provided at the bottom of the slit SLT is removed, so that the conductor layer 21 is partially exposed at the bottom of the slit SLT. A conductor (contact LI) is formed in the slit SLT, and a portion of the conductor formed outside the slit SLT is removed by, for example, the CMP (Chemical Mechanical Polishing). Thereafter, between the slits SLT adjacent to each other in the Y direction, a plurality of grooves parallel to the slits SLT are formed. Insulating films are filled in the grooves, so that the slits SHE in FIG. 5 are formed dividing the conductor layer 24 in the Y direction.

The laminated wiring structure in the memory cell array 10 is formed by performing the manufacturing steps described above. A series of the processes to replace the sacrificial members 60, 61, and 62 respectively with the conductor layers 22, 23, and 24 may be referred to as “replacement step”. The manufacturing steps described above are merely an example, and the manufacturing method is not limited to these manufacturing steps. For example, an additional process may be inserted between the manufacturing steps, or some of the steps may be omitted or integrated. For example, a step of forming a staircase structure of laminated wirings may be inserted between the steps illustrated in FIGS. 8 and 9.

The step of forming memory holes MH illustrated in FIG. 9 is described below in more detail.

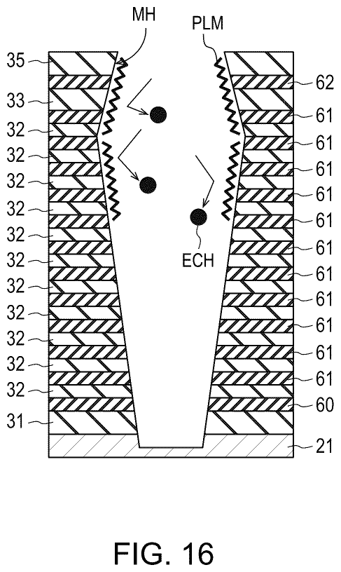

FIGS. 16 to 19 are cross-sectional views illustrating an example of the step of forming a memory hole according to the first embodiment.

The memory holes MH illustrated in FIG. 9 are formed in a laminated structure by using the lithography technique and the dry etching technique such as the RIE (Reactive Ion Etching) method. The structure is formed of the sacrificial members 60, 61, and 62 and the insulator layers 31, 32, 33, and 35 laminated one after another as illustrated in FIG. 8. The memory holes MH are formed in such a manner as to extend through and penetrate this structure in the Z direction. The lower end of the memory holes MH reaches the conductor layer 21.

At this time, the diameter of the memory holes MH is reduced toward their bottom portion and increased toward their top portion. Furthermore, in proximity to the opening of the memory holes MH, the diameter of the memory holes MH is slightly reduced. The difference in diameter between the upper portion and the lower portion of the memory holes MH appears more significantly when the memory holes MH have a high aspect ratio (for example, 100 or higher). The upper opening diameter of the memory holes MH is, for example, 110 nm to 120 nm, and the depth of the memory holes MH is, for example, 14 μm. In this case, the difference in diameter between the upper portion and the lower portion of the memory holes MH becomes significant. The significant difference in diameter between the upper portion and the lower portion of the memory holes MH may cause a device fault to occur. Such a tapered shape of the memory holes MH is considered to be caused by the loading effect in the etching step.

In view of that, in the present embodiment, in order to reduce the difference in diameter between the upper portion and the lower portion of the memory holes MH, the wet etching step (recess step) is performed in the following manner.

As illustrated in FIG. 16, the structure is etched from the inside of the memory hole MH by using a chemical etching solution for the recess step. This chemical etching solution contains an acid ECH that serves as an etchant, and a polymer PLM that protects the structure from the acid ECH. Examples of the acid ECH include hydrofluoric acid (HF), nitric acid (HNO₃), sulfuric acid (H₂SO₄), hydrochloric acid (HCl), acetic acid (CH₃COOH), and phosphoric acid (H₃PO₄). The polymer PLM is, for example, an organic polymer, and furthermore, an organic amine or an organic amine salt. Examples of the organic amine to be added to the chemical etching solution include polyalkylenimine (polyethyleneimine, polypropyleneimine, or polybutyleneimine). Examples of the organic amine salt include a hydrochloride salt and a nitrate salt. Furthermore, as the organic polymer, polyethylene glycol, polypropylene glycol, or polybutylene glycol may be added to the chemical etching solution.

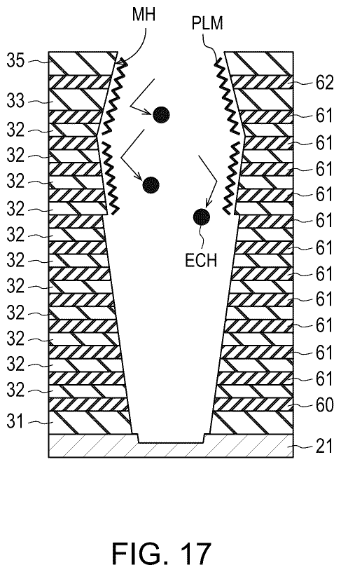

More specifically, the chemical etching solution is prepared by adding buffered hydrofluoric acid (BHF) as an example of the acid ECH, and polyethyleneimine (PEI) as an example of the polymer PLM. In the chemical etching solution, the polymer PLM described above may be added to a mixed acid as the acid ECH, which contains, for example, inorganic acid, oxidizing agent, carboxylic acid, and water. PEI has a molecular weight of, for example, 600 to 70000, and its additive concentration is adjusted within the range from 0.05 wt % to 10 wt %. In the recess step using this chemical etching solution, the acid ECH quickly reaches the lower portion of the memory hole MH while the added polymer PLM protects the surface of the upper portion of the memory hole MH. The polymer PLM has a molecular weight of 600 to 70000 greater relative to the acid ECH, and thus diffuses more slowly than the acid ECH. Therefore, while the polymer PLM coats the upper portion of the memory hole MH with an aspect ratio of 100 or higher, a relatively long time is required for the polymer PLM to reach the lower portion of the memory hole MH. In contrast, the acid ECH that serves as an etchant diffuses faster than the polymer PLM, and thus quickly reaches the lower portion of the memory hole MH. Accordingly, the acid ECH etches the inner wall more in the lower portion of the memory hole MH than in the upper portion. As illustrated in FIG. 17, this can promote the etching in the lower portion of the memory hole MH, while reducing the amount of the etching in the upper portion.

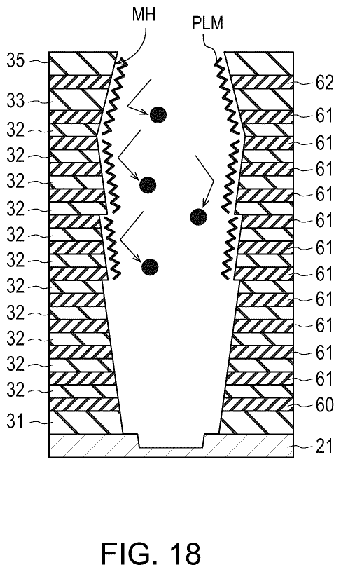

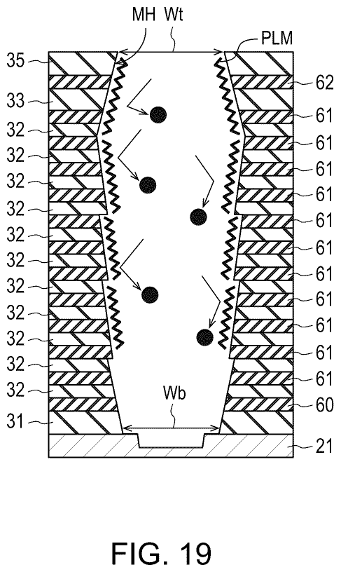

Further, as illustrated in FIGS. 18 and 19, as the polymer PLM diffuses gradually to the lower portion of the memory hole MH, the polymer PLM coats and protects the inner wall of the memory hole MH gradually from the upper portion to the lower portion. As a result, the etching amount in this recess step increases gradually from the upper portion toward the lower portion of the memory hole MH.

That is, the recess step using the chemical etching solution according to the present embodiment exerts such an effect on the memory hole MH as to reduce the difference in diameter between the upper portion and the lower portion of the memory hole MH (inverse loading effect). Consequently, it is possible for the memory hole MH to have a less tapered shape. As illustrated in FIG. 19, it is possible for the memory hole MH to have a bottom opening diameter Wb equal to or larger than a top opening diameter Wt. This results in an improvement in yield and reliability of the device.

FIG. 19 illustrates, for the sake of convenience, that there are steps on the inner wall of the memory hole MH from its upper portion to lower portion, however, in the actual state of the inner wall, it has become more smoothed depending on the molecular weight of the polymer PLM.

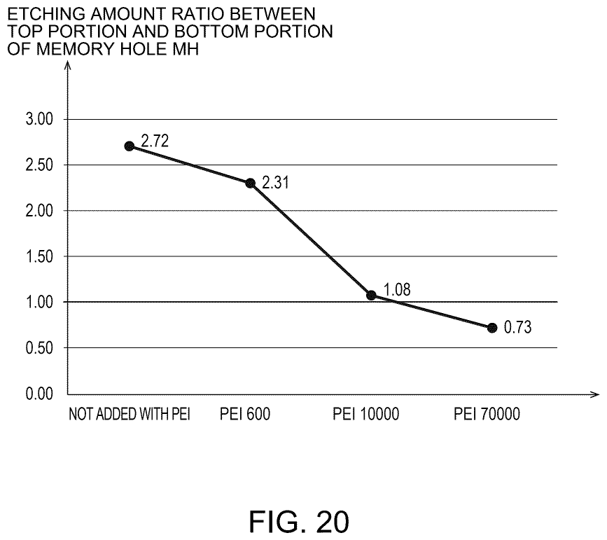

As the molecular weight of the polymer PLM decreases, the polymer PLM diffuses faster to the lower portion of the memory hole MH. In this case, the inverse loading effect becomes less significant, which prevents the tapered shape of the memory hole MH from being adequately corrected. It is therefore preferable that the molecular weight of the polymer PLM is relatively high. For example, as illustrated in FIG. 20, it was found through the experiments that the molecular weight of PEI used as the polymer PLM is preferably 600 or more, and more preferably 10000 or more.

Experimentally, in a case where the polymer PLM is polyethylene glycol (PEG), it was found that even if the molecular weight of the PEG is 5000000, the effects of the present embodiment can still be obtained. However, since the polymer PLM with its molecular weight of 5000000 or more is not commercially available, the upper limit of the molecular weight is set at 5000000. It is therefore preferable that the molecular weight of the polymer PLM is 600 to 5000000. In a case where PEI is used as the polymer PLM, the upper limit of the molecular weight for PEI is set at 70000 since PEI with its molecular weight of 70000 or more is not commercially available.

Whether polyethyleneimine is contained in the chemical solution can be determined based on an analysis using the infrared spectroscopy method FT-IR (Fourier Transform Infrared Spectroscopy), and the NMR (Nuclear Magnetic Resonance). It is also possible to calculate the weight-average molecular weight of polyethyleneimine contained in the chemical solution by using the GPC (Gel Permeation Chromatography).

FIG. 20 is a graph illustrating a relationship between the molecular weight of PEI and the inverse loading effect. The vertical axis represents the ratio between the etching amount at the bottom portion of the memory hole MH and the etching amount at the top portion of the memory hole MH (top etching amount/bottom etching amount). The horizontal axis represents the molecular weight of PEI. The etching amount ratio can be derived by, for example, performing the manufacturing method in the first embodiment on conditions with different etching rates between the insulator layer 33 and the insulator layers 32, and then calculating the ratio of the dimensions of the steps formed due to the difference in the etching rate between the insulator layer 33 and the insulator layers 32.

Referring to this graph, when the molecular weight of PEI is 600 or more, the etching amount ratio decreases, and when the molecular weight of PEI is 10000 or more, the etching amount ratio is equal to or lower than 1. That is, the etching amount of the bottom portion of the memory hole MH is larger than the etching amount of the top portion due to the inverse loading effect. Therefore, the molecular weight of PEI is preferably 600 or more, and more preferably 10000 or more.

### (First Modification)

The above recess step is applicable to the step of forming a slit SLT illustrated in FIG. 11. That is, the slit SLT is formed in the structure in the memory area MA in such a manner that the slit SLT reaches the conductor layer 21 by using the lithography technique and the dry etching technique such as the RIE method. The slit SLT is formed in such a manner as to divide the structure of the insulator layers 31, 32, 33, 35, and 36 and the sacrificial members 60, 61, and 62. At this time, the slit SLT has a tapered shape due to a large difference in diameter between the upper portion and the lower portion due to the loading effect in cross-section parallel to the Y-Z plane.

Next, in the recess step, the slit SLT is etched using a chemical etching solution containing the acid ECH and the polymer PLM described above. This etching exerts such an effect on the slit SLT as to reduce the difference in diameter between the upper portion and the lower portion of the slit SLT (inverse loading effect). Consequently, it is possible for the slit SLT to have a less tapered shape.

In the manner as described above, the recess step according to the present embodiment is also applicable to the step of forming a slit SLT.

### (Second Modification)

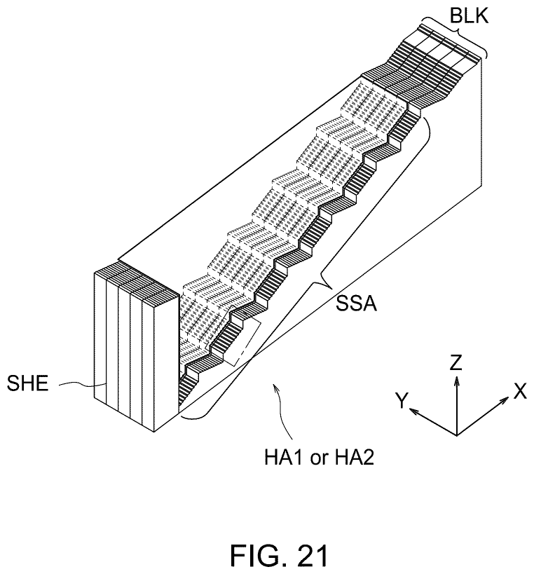

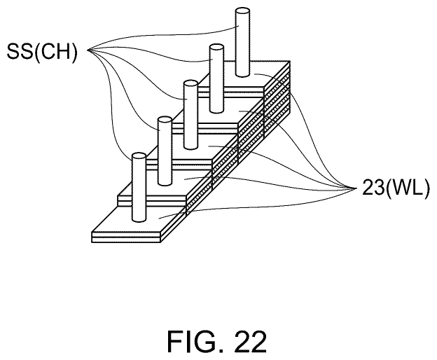

FIGS. 21 and 22 are perspective views illustrating an example of a configuration of a lead-out area according to a second modification of the first embodiment. FIGS. 21 and 22 schematically illustrate a lead-out area HA1 or HA2 of a certain block BLK. A staircase portion SSA of the lead-out areas HA1 and HA2 is provided at opposite end portions of the memory area MA in the X direction in FIG. 3. The staircase portion SSA is formed in such a manner as to be exposed from the memory area MA when the conductor layers 23 (word lines WL) are viewed in the Z direction in which the conductor layers 23 are laminated. Although not illustrated, the staircase portion SSA is coated with an interlayer dielectric film such as a silicon oxide film.

As illustrated in FIG. 22, in the staircase portion SSA, a plurality of conductor layers 23 (word lines WL) are formed in a staircase pattern. Contact plugs CC extend in the Z direction through the interlayer dielectric film, and are connected respectively to the plurality of conductor layers 23 (word lines WL). For example, a conductive metal material such as tungsten is used for the contact plugs CC.

The contact plugs CC are electrically connected to the CMOS such as a row decoder provided under the memory cell array 10 through an upper layer wiring and another contact plug (not illustrated). With this configuration, the row decoder can control the voltage of each of the conductor layers 23 (word lines WL) through the contact plugs CC.

The above recess step is also applicable to the formation of the contact plugs CC described above. That is, opposite ends of the structure of the insulator layers 31, 32, 33, 35, and 36 and the sacrificial members 60, 61, and 62 in the X direction are processed into a staircase pattern to undergo the replacement step. The structure is coated with the interlayer dielectric film (not illustrated). After the replacement step, contact holes CH are formed through the interlayer dielectric film in such a manner as to reach each of the conductor layers 23 by using the lithography technique and the dry etching technique such as the RIE method. At this time, each of the contact holes CH has a tapered shape due to a large difference in diameter between the upper portion and the lower portion of the contact holes CH due to the loading effect.

Next, in the recess step, the contact holes CH are etched using a chemical etching solution containing the acid ECH and the polymer PLM described above. This etching exerts such an effect on the contact holes CH as to reduce the difference in diameter between the upper portion and the lower portion of the contact holes CH (inverse loading effect). Consequently, it is possible for the contact holes CH to have a less tapered shape.

In the manner as described above, the recess step according to the present embodiment is also applicable to the step of forming contact plugs CC.

The recess step according to the present embodiment is not limited to the above step, and is applicable to the step of forming a hole or a slit with a high aspect ratio.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An etching method comprising etching a structure from inside of a hole or a slit provided in the structure, using a chemical etching solution containing an acid and a polymer.

2. The method of claim 1, wherein the polymer is an organic polymer.

3. The method of claim 2, wherein the organic polymer is an organic amine or an organic amine salt.

4. The method of claim 3, wherein the organic amine is polyalkylenimine.

5. The method of claim 3, wherein the organic amine is polyethyleneimine, polypropyleneimine, or polybutyleneimine.

6. The method of claim 2, wherein the organic polymer is polyethylene glycol, polypropylene glycol, or polybutylene glycol.

7. The method of claim 1, wherein
a molecular weight of the polymer is 600 to 5000000, and
the molecular weight is 10000 to 70000 when the polymer is polyethyleneimine.

8. The method of claim 1, wherein the structure has an aspect ratio of 100 or higher.

9. The method of claim 1, wherein the structure is a laminated body of sacrificial members and insulator layers laminated alternately in a first direction.

10. A manufacturing method of a semiconductor device, the method comprising etching a structure from inside of a hole or a slit provided in the structure, using a chemical etching solution containing an acid and a polymer.

11. The method of claim 10, wherein the polymer is an organic polymer.

12. The method of claim 11, wherein the organic polymer is an organic amine or an organic amine salt.

13. The method of claim 12, wherein the organic amine is polyalkylenimine.

14. The method of claim 12, wherein the organic amine is polyethyleneimine, polypropyleneimine, or polybutyleneimine.

15. The method of claim 11, wherein the organic polymer is polyethylene glycol, polypropylene glycol, or polybutylene glycol.

16. The method of claim 10, wherein
a molecular weight of the polymer is 600 to 5000000, and
the molecular weight is 10000 to 70000 when the polymer is polyethyleneimine.

17. The method of claim 10, wherein the structure has an aspect ratio of 100 or higher.

18. The method of claim 10, further comprising:
laminating sacrificial members and insulator layers alternately in a first direction to form the structure;
forming a hole extending in the structure in the first direction;
etching the structure from inside of the hole, using the chemical etching solution;
forming a columnar body including a laminated film and a semiconductor layer in the hole;
removing the sacrificial members; and
after removing the sacrificial members, filling a material of a conductor in a space, from which the sacrificial members have been removed, to form a conductive layer between the insulator layers adjacent to each other in the first direction.

19. The method of claim 18, further comprising:
after formation of the columnar body,
forming a slit dividing the structure; and
etching the structure from inside of the slit, using the chemical etching solution, wherein
the sacrificial members are etched and removed through the slit, and
a material of the conductor is filled in the space through the slit.

20. The method of claim 19, further comprising:
processing an end portion of the structure into a staircase pattern;
forming an interlayer dielectric film on the structure;
forming a contact hole extending through the interlayer dielectric film in the first direction and reaching each conductive layer;
etching the structure from inside of the contact hole, using the chemical etching solution; and
forming a conductive material in the contact hole to form a contact plug electrically connecting to each conductive layer.
